(19) United States
(12) Patent Application Publication
(10) Pub. No.: US 2025/0166955 A1
(43) Pub. Date: May 22, 2025

(54) BEAM MANIPULATION USING CHARGE REGULATOR IN A CHARGED PARTICLE SYSTEM

(71) Applicant: ASML Netherlands B.V., Veldhoven (NL)

(72) Inventors: Ning YE, San Jose, CA (US); Jian ZHANG, San Jose, CA (US); Zhonghua DONG, San Jose, CA (US); Datong ZHANG, San Jose, CA (US)

(73) Assignee: ASML Netherlands B.V., Veldhoven (NL)

(21) Appl. No.: 18/840,309

(22) PCT Filed: Jan. 31, 2023
(86) PCT No.: PCT/EP2023/052248

§ 371 Date: Aug. 21, 2024

Related U.S. Application Data
(60) Provisional application No. 63/313,228, filed on Feb. 23, 2022.

(51) Int. Cl. H01J 37/02; H01J 37/28

(52) U.S. Cl. CPC H01J 37/026; H01J 37/28; H01J 2237/0047

(57) ABSTRACT

A system and a method for controlling a beam spot of an Advanced Charge Controller module in an electron beam system. The Advanced Charge Controller module includes a MEMS mirror configured to steer and shape the beam in order to perform beam alignment, increase the power density at an area of interest and modulate the power density in real time.

### CROSS-REFERENCE TO RELATED APPLICATIONS

This application claims priority of U.S. application 63/313,228 which was filed on 23 Feb. 2022 and which is incorporated herein in its entirety by reference.

### TECHNICAL FIELD

The present disclosure generally relates to the field of charged particle beam systems, and more particularly, to providing a beam for regulating charges on a sample surface of a charged particle beam system.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beamlets, can be focused on locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

Meanwhile, irradiating the wafer with primary electrons may cause the surface of the wafer to become charged. Surface charging may influence the interactions of the primary electrons with the wafer and may cause variations in imaging conditions. A charge regulator, such as an Advanced Charge Controller (ACC), may be used to compensate for charging effects and may help to improve image quality. Furthermore, some applications, such as voltage contrast imaging, may use ACCs to condition a surface for imaging. However, there are increasing demands for manipulating ACC power in the e-beam inspection tool with greater magnitude, range and accuracy. Improvements in various aspects of charge regulators are desired.

### SUMMARY

Embodiments consistent with the present disclosure include a charge regulator for a charged particle beam tool. The charge regulator includes a light source configured to emit a beam; a beam manipulator configured to manipulate the beam; and a controller configured to control the beam manipulator to adjust a property of a beam spot formed by the beam on a sample surface in relation to a charged particle beam projected on the sample surface.

In some embodiments, the property may be a position of the beam spot. In some embodiments, the property may be a shape of the beam spot. In some embodiments, the property may be size of the beam spot. In some embodiments, the property may be a spatial intensity distribution of the beam spot.

In some embodiments, the controller is configured to control the beam manipulator to scan the beam spot along the sample surface. In some embodiments, the beam spot scanning direction is substantially parallel to a charged particle beam scanning direction of the charged particle beam projected on the sample surface. In some embodiments, the controller is configured to control the beam spot to follow the charged particle beam along the charged particle beam scanning direction. In some embodiments, the beam spot is scanned ahead of the charged particle beam with a time offset.

In some embodiments, the beam spot comprises an intensity distribution having a first region and a second region, the first region having a higher intensity than the second region; and the controller is configured to control the beam manipulator to position the second region over an area of interest in a field of view of a charged particle beam tool during the projection of the charged particle beam on the sample surface. In some embodiments, the controller is configured to control the beam manipulator to adjust a position of the beam spot a plurality of times during the projection of the charged particle beam on the sample surface to average out speckle effects of the laser spot.

In some embodiments, the controller is configured to control the beam manipulator to condense the beam spot on the sample surface. In some embodiments, the condensed spot has an area of less than 50% of an area of a field of view of a charged particle beam tool that projects the charged particle beam on the sample surface.

In some embodiments, the controller is configured to control the beam manipulator to correct a misalignment between the beam spot and a field of view of a charged particle beam tool that projects the charged particle beam on the sample surface. In some embodiments, the correcting the misalignment is based on measurements from an alignment detector of a charged particle beam tool.

In some embodiments, the charge regulator comprises a plurality of light sources configured to emit a plurality of beams and an optical element configured to receive the plurality of beams. In some embodiments, the beam manipulator is configured to receive the plurality of beams from the optical element and overlap the plurality of beams onto a common portion of the sample surface. In some embodiments, the charge regulator comprises a plurality of beam manipulators, wherein the plurality of beam manipulators is configured to direct the plurality of beams to the optical element and overlap the plurality of beams onto a common portion of the sample surface. In some embodiments, the optical element comprises a dichroic mirror

Further objects and advantages of the disclosed embodiments will be set forth in part in the following description, and in part will be apparent from the description, or may be learned by practice of the embodiments. Some objects and advantages of the disclosed embodiments may be realized and attained by the elements and combinations set forth in the claims. However, embodiments of the present disclosure are not necessarily required to achieve such exemplary objects or advantages, and some embodiments may not achieve any of the stated objects or advantages.

It is to be understood that both the foregoing general description and the following detailed description are exemplary and explanatory only and are not restrictive of the disclosed embodiments, as may be claimed.

### BRIEF DESCRIPTION OF DRAWINGS

FIG. 1 illustrates an exemplary electron beam inspection (EBI) system 100, consistent with embodiments of the present disclosure.

FIG. 2A is a schematic diagram illustrating an exemplary electron beam tool, consistent with embodiments of the present disclosure that may be a part of the exemplary EBI system of FIG. 1.

FIG. 2B is a schematic diagram illustrating an exemplary electron beam tool, consistent with embodiments of the present disclosure that may be a part of the exemplary EBI system of FIG. 1.

FIG. 2C is a schematic diagram illustrating an exemplary multi-beam electron beam tool, consistent with embodiments of the present disclosure that may be a part of the exemplary EBI system of FIG. 1.

FIG. 3A illustrates a top view of sample under inspection according to a comparative ACC module.

FIG. 3B illustrates an intensity distribution according to a comparative ACC module.

FIG. 3C illustrates a top view of sample under inspection consistent with embodiments of the present disclosure.

FIG. 4A, FIG. 4B and FIG. 4C illustrate a scanning operation of an ACC module consistent with embodiments of the present disclosure.

FIG. 5A, FIG. 5B and FIG. 5C illustrate a laser spot shifting operation of an ACC module consistent with embodiments of the present disclosure.

FIG. 6 illustrates a time offset scanning operation of an ACC module consistent with embodiments of the present disclosure.

FIG. 7 illustrates a series of SEM images consistent with embodiments of the present disclosure.

FIG. 8 illustrates a top view of a misaligned ACC beam consistent with embodiments of the present disclosure.

FIG. 9 illustrates a view of a detection operation of an electron beam tool consistent with embodiments of the present disclosure.

FIG. 10A illustrates an ACC module consistent with embodiments of the present disclosure.

FIG. 10B illustrates a MEMS mirror arrangement consistent with embodiments of the present disclosure.

FIG. 10C illustrates a MEMS mirror arrangement consistent with embodiments of the present disclosure.

FIG. 11 illustrates a charge control method consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to subject matter described herein.

Electronic devices are constructed of circuits formed on a substrate of material such as silicon. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

During operation of a SEM, a primary charged-particle beam, such as an electron beam (e-beam), is scanned over a semiconductor wafer and then an image of the wafer surface can be generated by detecting a secondary beam of charged particles emitted from the wafer surface. When the charged-particle beam scans the wafer, charges may be accumulated on the wafer due to large beam current, which may affect the quality of the image. To regulate the accumulated charges on the wafer, an Advanced Charge Controller (ACC) module can be employed that projects a light beam, such as a laser beam, on the wafer, so as to control the accumulated charges due to effects such as photoconductivity, photoelectric, or thermal effects. It is important to improve the performance of the ACC module so as to effectively control the accumulated charges, thus enhancing imaging.

As the chip industry continues to develop, there are increasing demands for manipulating ACC power in the e-beam inspection tool with greater magnitude, range and accuracy. A straight-forward solution to increasing the power of the ACC would be to provide a more powerful laser source. But it is difficult and costly to develop a suitable laser of significantly higher power than those in use today. Furthermore, existing lasers used in ACCs may use power inefficiently.

Additionally, some applications require more flexibility in charge regulators than what current products can offer. For example, in voltage contrast (VC) imaging, charge is purposely applied to a surface in order to make certain types of defective structures visible. An ACC may be used in VC imaging to apply surface charge, but there is a need to modulate ACC power in order to provide VC signals tailored to the characteristics of the devices under inspection. For instance, certain types of high-resistance defects can be more easily detected when a particular ACC power level is used. In conventional systems, one solution may be to modulate the input power to the ACC laser itself, but this strategy may face the following issues. First, it takes a relatively long time to achieve stable ACC power levels after each modulation, which affects throughput. That is, the process must account for some extra settling time. Second, the laser spot has a non-uniform intensity distribution over the field of view of the SEM. For a laser spot that remains stationary during an e-beam scan, this creates a variation in detection sensitivity for different locations within the same field of view. Finally, there is a concern that repeated modulation of input power may negatively impact the lifetime of the laser, which may be especially important in high volume manufacturing (HVM) applications. Further still, ACC modules require maintenance such as periodic alignment adjustment. When this adjustment is performed manually, the SEM and related equipment must be taken offline. In some cases, a human operator must physically enter the environment and make mechanical adjustments. Such processes are prone to error and lack of consistency. Embodiments consistent with the present disclosure include systems and methods for regulating sample surface charges in an electron beam (e-beam) system. In some embodiments, there may be a system that includes an e-beam tool. The system also includes a charge regulator, such as an Advanced Charge Controller (ACC) module comprising a light source such as a laser. The laser irradiates a sample under inspection, such as a wafer, during an e-beam scan. The optical beam of the ACC may be applied to create charges or modify the electrical properties near the inspected wafer surface to improve the voltage contrast (VC) signal in e-beam inspection. The ACC module further comprises one or more Microelectromechanical Systems (MEMS) mirrors configured to move the laser spot along the wafer surface and control the spot shape in real-time. System and methods consistent with the disclosure may achieve several advantages over conventional systems.

First, the MEMS mirror system is able to concentrate the laser spot onto the region being actually exposed by the e-beam. Because the MEMS mirror can cause the laser spot to follow the e-beam as it scans, the light does not have to be distributed over an entire field of view of the e-beam tool. This greatly improves laser power density at the exposed region without requiring a more powerful light source.

Second, the MEMS mirror can move the laser spot to different areas in the e-beam tool's field of view. This allows the system to take advantage of the variations in a laser spot intensity distribution as a way of modulating power density. By locating different portions of the laser spot (e.g., a central portion or a peripheral portion) over the area being exposed by the e-beam, the system can rapidly switch between multiple power density levels.

Third, the MEMS mirror can perform remote alignment and calibration of the laser spot. Conventional systems required an operator to crawl into a SEM chamber and manually adjust the ACC alignment, resulting in large amounts of downtime. Embodiments of the present disclosure allow such alignment to be performed remotely, even during operation of the e-beam tool, such that downtime due to spot alignment is reduced or eliminated entirely.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

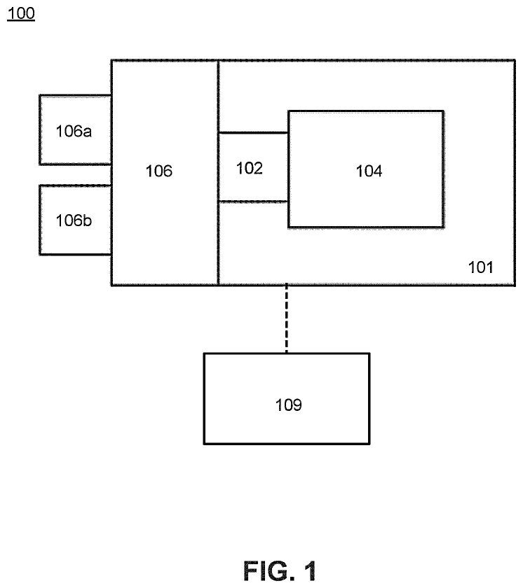

FIG. 1 illustrates an exemplary electron beam inspection (EBI) system 100 consistent with embodiments of the present disclosure. While this and other examples refer to an electron beam system, it is appreciated that the techniques disclosed herein are applicable to systems other than electron beam systems, such as an ellipsometer, a velocimeter, a CO₂ laser (e.g., for machining), non-electron beam systems where a beam projection spot may be optimized but the space is limited, among others. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be collectively referred to as “wafers” herein).

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 can part of the structure.

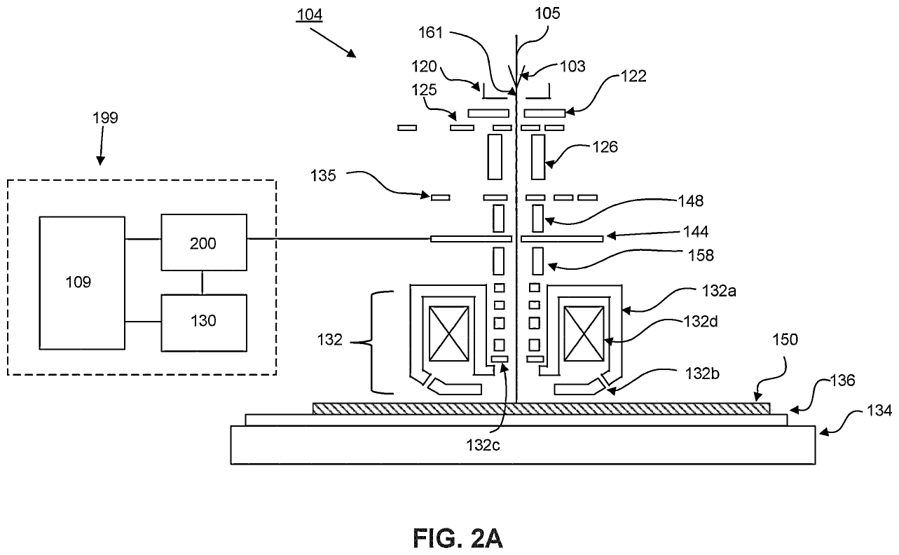

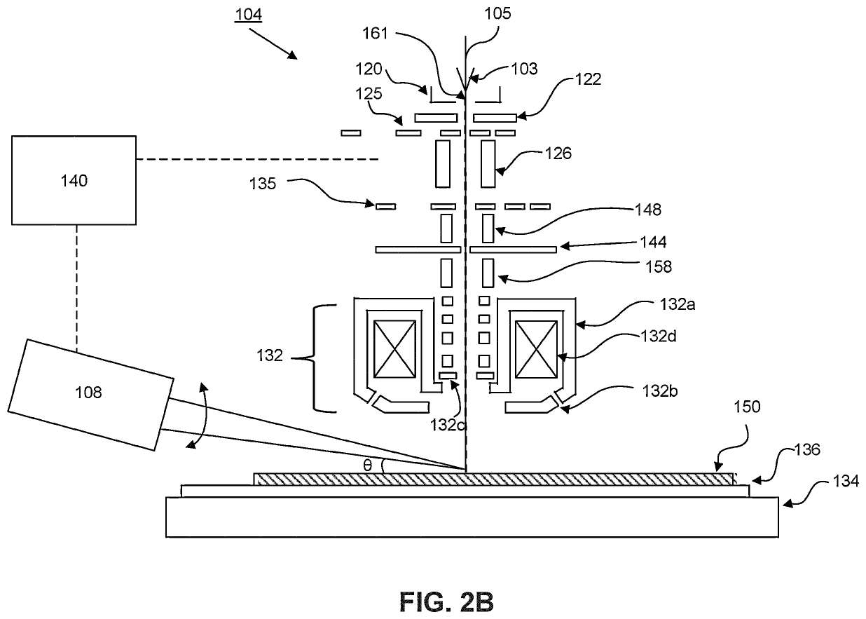

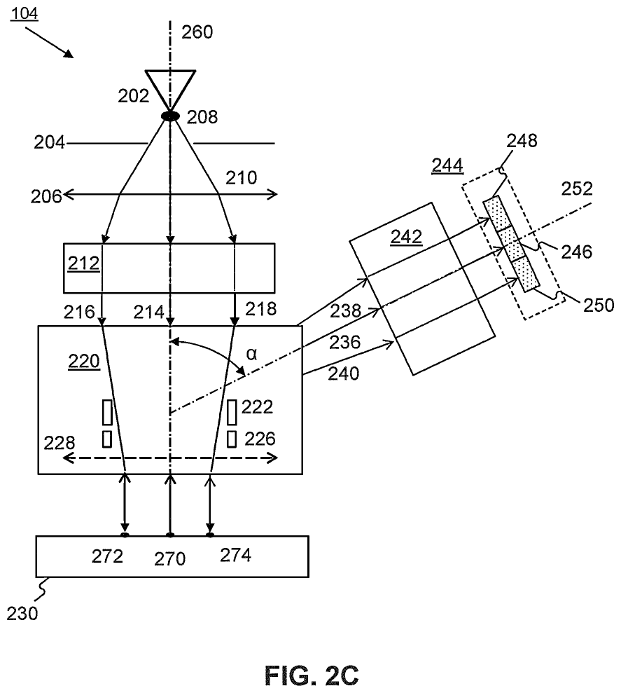

FIG. 2A illustrates a charged particle beam apparatus in which an electron beam system may comprise a single primary beam that may be configured to generate a secondary beam. A detector may be placed along an optical axis 105, as shown in FIG. 2A. In some embodiments, a detector may be arranged off axis.

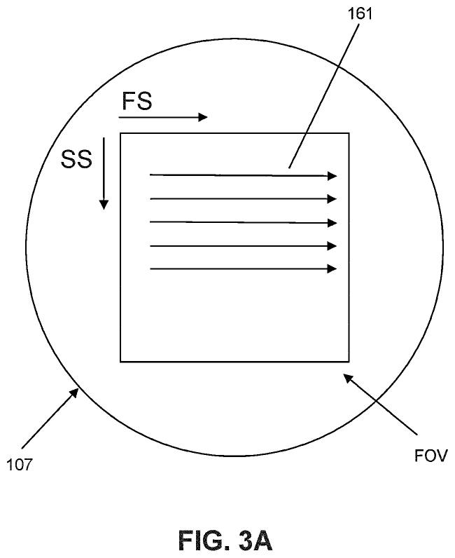

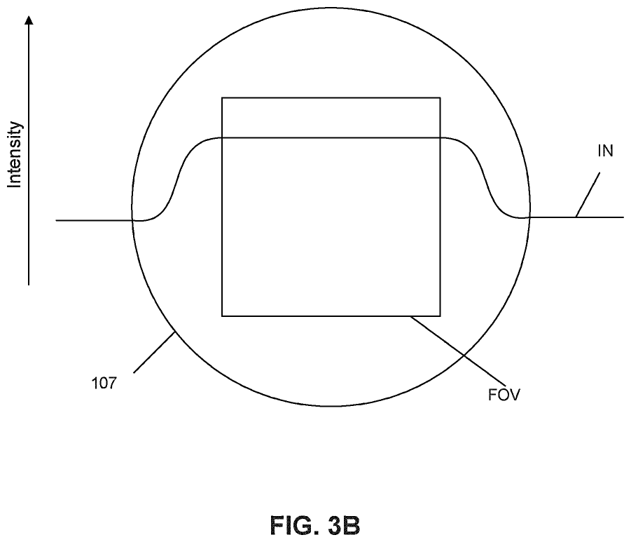

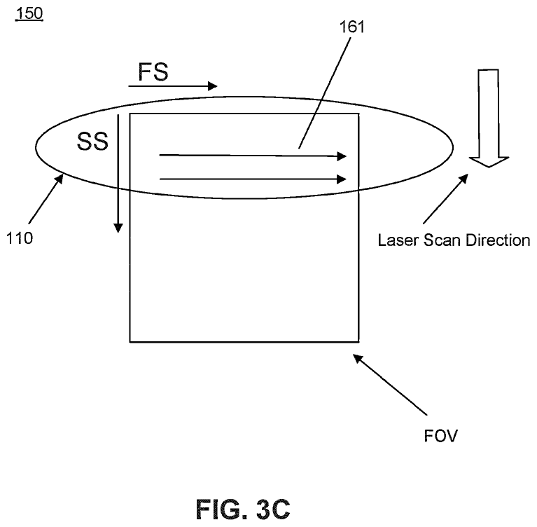

As shown in FIG. 2A, an electron beam tool 104 may include a wafer holder 136 supported by motorized stage 134 to hold a wafer 150 to be inspected. Electron beam tool 104 includes an electron beam source, which may comprise a cathode 103, an anode 120, and a gun aperture 122. Electron beam tool 104 further includes a beam limit aperture 125, a condenser lens 126, a column aperture 135, an objective lens assembly 132, and an electron detector 144. Objective lens assembly 132, in some embodiments, may be a modified swing objective retarding immersion lens (SORIL), which includes a pole piece 132a, a control electrode 132b, a deflector 132c, and an exciting coil 132d. In an imaging process, an electron beam 161 emanating from the tip of cathode 103 may be accelerated by anode 120 voltage, pass through gun aperture 122, beam limit aperture 125, condenser lens 126, and focused into a probe spot by the modified SORIL lens and then impinge onto the surface of wafer 150. The probe spot may be scanned across the surface of wafer 150 by a deflector, such as deflector 132c or other deflectors in the SORIL lens. Deflectors may be used to scan beam 161 along various directions on the surface of wafer 150. The various directions may include a first direction and a second direction. The first and second directions may be orthogonal to one another. As further discussed below with respect to FIG. 3, the deflectors may scan beam 161 to move in a raster pattern along two different directions, a fast scan (FS) and a slow scan (SS) direction, to cover the field of view (FOV) of electron beam tool 104. In some embodiments, the entire FOV may be covered using only the FS and SS directions.

Secondary or backscattered electrons emanated from the wafer surface may be collected by detector 144 to form an image of an area of interest on wafer 150. Properties (e.g., energy, intensity, number) of the electrons received on detector 144 may be used to form a picture of the sample under inspection. There may also be provided an image processing system 199 that includes an image acquirer 200, a storage 130, and controller 109. Image acquirer 200 may comprise one or more processors. For example, image acquirer 200 may comprise a computer, server, mainframe host, terminals, personal computer, any kind of mobile computing devices, and the like, or a combination thereof. Image acquirer 200 may connect with detector 144 of electron beam tool 104 through a medium such as an electrical conductor, optical fiber cable, portable storage media, IR, Bluetooth, internet, wireless network, wireless radio, or a combination thereof. Image acquirer 200 may receive a signal from detector 144 and may construct an image. Image acquirer 200 may thus acquire images of wafer 150. Image acquirer 200 may also perform various post-processing functions, such as generating contours, superimposing indicators on an acquired image, and the like. Image acquirer 200 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 200 and may be used for saving scanned raw image data as original images, and post-processed images. Image acquirer 200 and storage 130 may be connected to controller 109. In some embodiments, image acquirer 200, storage 130, and controller 109 may be integrated together as one control unit.

In some embodiments, image acquirer 200 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2A, the electron beam tool 104 may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

Although FIG. 2A shows electron beam tool 104 as a single-beam inspection tool that may use only one primary electron beam to scan one location of wafer 150 at a time, embodiments of the present disclosure are not so limited. For example, electron beam tool 104 may also be a multi-beam inspection tool (such as that shown in FIG. 2C) that employs multiple primary electron beamlets to simultaneously scan multiple locations on wafer 150.

FIG. 2B illustrates a charged particle beam apparatus with a charge regulator 108, consistent with embodiments of the present disclosure. Charge regulator 108 may include an ACC module for directing an illumination beam (e.g., a light beam, a laser beam, or other form of emitted energy) to a spot on a wafer during inspection. The components of FIG. 2B are similar to those of FIG. 2A, except that FIG. 2B includes charge regulator 108 with ACC module. The ACC module further comprises a MEMS mirror (not shown in FIG. 2B) configured to shape and steer beam spot formed by the illumination beam as depicted schematically by double-headed arrows in FIG. 2B. The illumination beam emitted from charge regulator 108 may be configured to regulate accumulated charges on wafer 150 using photoconductivity or photoelectric effect, or a combination of photoconductivity and photoelectric effect, among others. The charge regulator 108 and electron beam unit 104 are coupled to an ACC controller 140 that controls operation of the charge regulator 108. ACC controller 140 may be integrated with controller 109. Charge regulator 108 may be positioned at a nominal angle θ, usually less than 30°, in order to project the illumination beam onto wafer 150 without landing on the column components of electron beam tool 104.

In some embodiments, charge regulator 108 may be implemented with a multi-beam system. FIG. 2C illustrates a multi-beam apparatus that may be an example of electron beam tool 104, consistent with embodiments of the present disclosure. The multi-beam apparatus uses a plurality of beamlets formed from a primary electron beam to simultaneously scan multiple locations on a wafer. Charge regulator 108 may adjust a beam spot formed by the illumination beam emitted therefrom to cover all beamlet spots. Alternatively, charge regulator 108 may produce multiple beam spots, or multiple charge regulators 108 may be provided, to accommodate the multiple electron beamlets.

As shown in FIG. 2C, electron beam tool 104 may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2C), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 104. Secondary optical system 242 and electron detection device 244 may be aligned with a secondary optical axis 252 of apparatus 104.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2C) and an array of beam-limit apertures (not shown in FIG. 2C). An example of source conversion unit 212 may be found in U.S. Pat. Nos. 9,691,586; 10,395,886; and International Publication No. WO 2018/122176, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Pat. No. 9,922,799, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

In some embodiments, the charge regulator may include an illumination beam manipulator. The illumination beam manipulator may be configured to manipulate beams emitted from the charge regulator. The illumination beam manipulator may change the shape, emission angle, or any other property of emitted illumination beams from the charge regulator. The illumination beam manipulator may include a beam steering module. The illumination beam manipulator may include deflectors, apertures, diffractive optical elements, Fresnel lenses, micro-lenses, MEMS mirrors, deformable membrane mirrors, grating light valves (GLV), digital micromirror devices (DMD), or any structures capable of manipulating properties of beams. For example, there may be provided MEMS mirrors used in the beam manipulator that comprise a piece or an array (e.g., a two-dimensional planar array) of mirror elements. Each mirror element may have an area, e.g., on the order of microns and may be independently controllable. When a beam of light illuminates the MEMS mirror surface, each individual mirror element can be actuated to deflect one portion of the beam cross-section in a desired way. Together the mirrors can rapidly steer the beam direction, modulate the beam shape and adjust other beam parameters.

FIGS. 3A-B illustrate a top view of wafer 150 during a comparative e-beam scan. Electron beam 161 is moved in a raster pattern. For example, electron beam 161 is deflected to scan a series of lines across wafer 150. The lines are scanned parallel to a fast scan direction FS and repeat along a slow scan direction SS. The lines cover substantially an entire field of view (FOV) of a region of sample inspected by electron beam tool 104. As the names suggest, the fast scan is a rapid scan of electron beam 161 at a high frequency while the slow scan is at a relatively lower frequency. After the electron beam tool completes a scan of one or more lines in the fast scan direction FS, the beam is deflected in the slow scan direction SS to begin a new set of one or more lines. In some embodiments, by way of example, the fast scanning bandwidth has a frequency of more than a few hundred kHz while the slow scanning bandwidth has a frequency of a few tens of Hz to a few kHz.

In FIGS. 3A-B, a beam spot 107 is shown that covers the FOV. Beam spot 107 may be a laser spot generated by an ACC module of charge regulator 108. Beam spot 107 may also be formed by other types of light or electromagnetic radiation. As shown in FIG. 3A, beam spot 107 has a fixed shape and position during the entire e-beam scan. Therefore, to properly regulate surface charges at every point in the scan, beam spot 107 must be large enough to cover the entire FOV. Additionally, beam spot 107 may have an intensity profile such as that shown in FIG. 3B. Beam spot 107 may have an intensity profile IN that has a “flat top” (e.g., having a substantially constant value at the central portion with a downward slope at its periphery). In order to achieve a sufficiently uniform intensity, the beam spot 107 must be expanded enough that peripheral regions are located substantially outside the FOV. This may result in a reduced power density compared to embodiments of the present disclosure.

FIG. 3C illustrates a top view of wafer 150 having a modified beam spot 110, consistent with some embodiments of the present disclosure. A MEMS mirror may be used to condense beam spot 110 onto the portion of the FOV that is actually being exposed by the primary electron beam of the electron beam tool. As electron beam 161 moves along the slow scan direction SS, the MEMS mirror is actuated to move the condensed beam spot 110 along with it. Beam spot 110 may move with electron beam 161 based on a predetermined relationship. For example, beam spot 110 may track with slow scan direction SS. Beam spot 110 may extend a predetermined length so as to cover the full range of movement of electron beam 161 along fast scan direction FS. Thus, in some embodiments, beam spot 110 need not track with fast scan direction FS. Beam spot 110 may be synchronized with movement of electron beam 161 along slow scan direction SS. In some embodiments, beam spot 110 may move a predetermined amount ahead or behind electron beam 161.

Properties of beam spot 110 may be manipulated by a beam manipulator, and a higher power density relative to an uncondensed beam may be achieved without changing the input power of the light source. If beam spot 110 is reduced to, e.g., 1/10 of its previous area, the ACC optical power density can be increased to 10 times what it was before. In some embodiments, the area of the condensed beam spot 110 is less than the area of the FOV. For example, the area of the condensed beam spot 110 can be less than 75%, 50%, 25%, 10% or less of the area of the FOV. According to some aspects of the present disclosure, ACC power density levels can be increased by 100 times or more compared to an uncondensed beam from the same light source with the same power input.

In some embodiments, beam spot 110 only irradiates each portion of wafer 150 at the time it is being scanned. The dwell time of laser irradiation on regions of interest of the sample may be reduced. This reduces the actual duration of irradiation for each portion, enabling a higher power density while mitigating the risk of thermal damage to the wafer. Finally, maintaining a constant input power may improve the lifetime of the light source. A light source in a charge regulator may be continuously operated at a substantially constant power level while beam manipulation is achieved using a beam manipulator, such as by using a MEMS mirror.

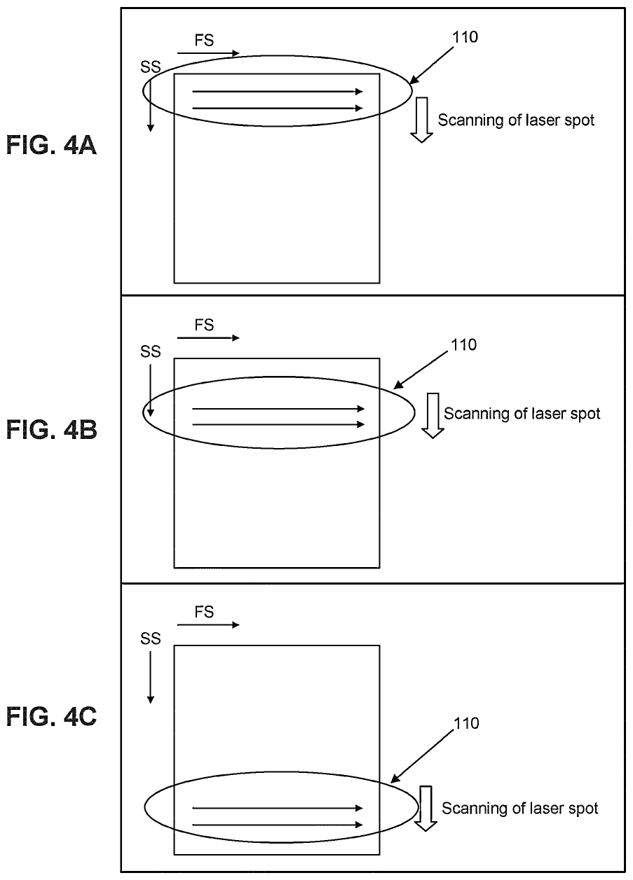

FIGS. 4A-C illustrate a laser scanning process, consistent with embodiments of the disclosure. At the beginning of an e-beam scan in FIG. 4A, a first set of lines are exposed along the fast scan direction FS at an upper portion of the FOV while beam spot 110 irradiates a region containing the lines. As more scan lines are successively exposed, e-beam 161 gradually moves down the FOV in the slow scan direction SS. In FIG. 4B, e-beam 161 is scanning a different set of lines at an intermediate portion of the FOV that is displaced from the original beam spot position of FIG. 4A. However, beam spot 110 can maintain its position over the new scan lines at the intermediate portion owing to the actuation of the beam manipulator (e.g., MEMS mirror). For instance, a MEMS mirror having a scanning bandwidth of, e.g., 25 kHz, can easily follow the electron beam along the entire FOV as it scans in the SS direction. As seen in FIG. 4C, beam spot 110 is at a lower portion near the end of an e-beam scan. Beam spot 110 can track the e-beam scan throughout the entire process.

In some embodiments, the MEMS mirrors may be actuated in the fast scan direction FS as well as the slow scan direction SS. By creating slight shifts in the FS direction between different frames during an e-beam imaging process, laser effects such as speckle may be averaged out and the overall intensity of the laser spot may become more uniform. Further, while the scanning action of beam spot 110 in the SS direction may achieve some averaging of speckle effects in the SS direction, additional shifting up or down along the SS direction during a scan is also possible.

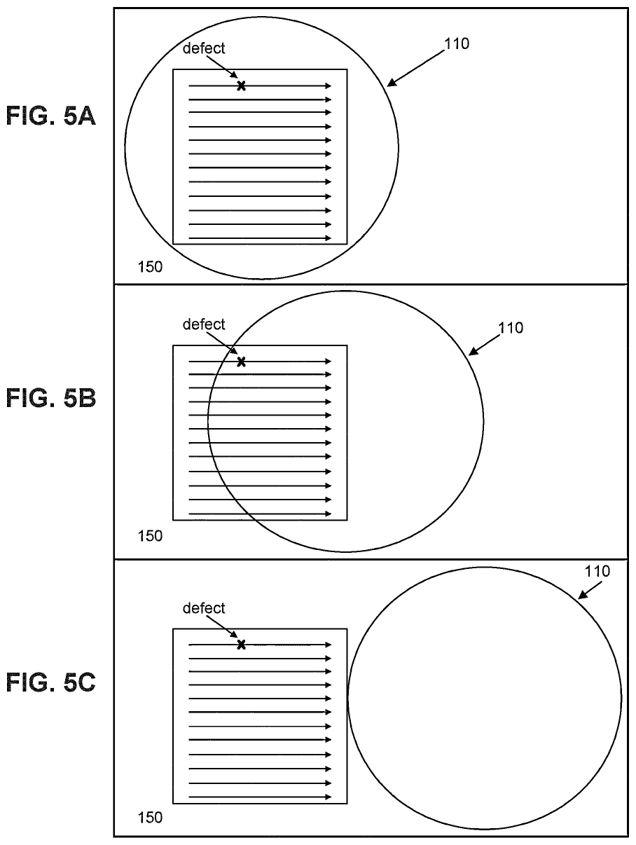

FIGS. 5A-C illustrate a view of wafer 150 according to some embodiments of the present disclosure. While beam spot 110 is depicted as circular in the present embodiment, it should be understood that other spot shapes may be used. FIGS. 5A-C show one way that a MEMS mirror can be used to achieve rapid power modulation in real-time. This allows for multiple SEM images to be taken of the same area under different charging conditions (e.g., different ACC conditions).

At FIG. 5A, beam spot 110 is centered on the FOV. When a defect X in an area of interest is imaged under this condition, it is exposed to a first region of the ACC beam spot intensity profile. The first region may be a central portion with a relatively high power density. Next at FIG. 5B, the MEMS mirror has moved beam spot 110 so that a different region of beam spot 110 is located over the same defect X, the region corresponding to a second region of the ACC beam spot intensity profile. The second region may be a peripheral portion having a relatively lower power density. For the flat top profile discussed with reference to FIG. 3B above, the placement of beam spot 110 as shown in FIG. 5B can be used to select a power density level corresponding to some point on the downward slope of the intensity curve IN. Other profiles may be used, e.g., to provide a greater number of selectable intensity values or for better selection accuracy. For example, an intensity profile could provide a larger and more gradual slope at the periphery, a radially stepped profile, a linear profile, a sharply sloped profile, or any profile formed so as to accommodate a desired shape. Finally, FIG. 5C shows a case in which the spot 110 is moved entirely out the area of interest. Here, no portion of beam spot 110 irradiates the defect X. It should be understood that the MEMS mirror can place beam spot 110 at any number of intermediate positions besides the three shown. By sweeping beam spot 110 across the FOV, e-beam tool 104 can take a series of SEM images under different ACC conditions.

In some embodiments, the charge regulator may be configured to move the beam spot with an offset relative to the primary beam of the charged particle beam apparatus. The offset may be a time-based offset or a space-based offset. The space-based offset may be based on a distance relative to the scanning position of the primary beam. For example, the space-based offset may be a predetermined distance relative to the scanning position of the primary beam.

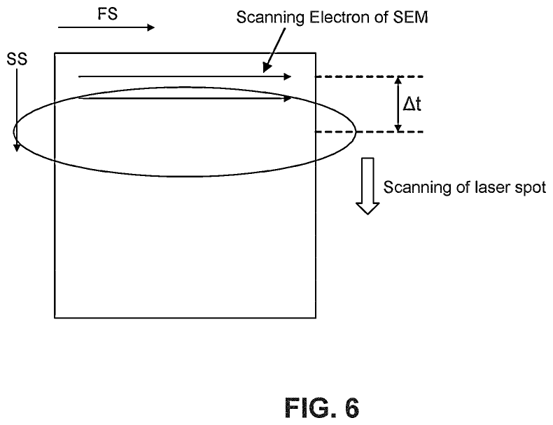

FIG. 6 demonstrates another technique for MEMS mirror power modulation, consistent with embodiments of the disclosure. In FIG. 6, the scanning of beam spot 110 takes place ahead of the e-beam scan in the SS direction according to a prescribed time offset Δt. Whereas, when the scanning of e-beam 161 and the scanning of beam spot 110 are synchronized, Δt=0. When Δt=0, the power density and optical charging conditions may be at a maximum. The optical charging conditions can be set to a desired characteristic by selecting a non-zero value for Δt. It is noted that this time delay is not necessarily identical to the spatial offset of FIGS. 5A-C. Here, the short delay in time can allow surface charge conditions at an area of interest to change in a predictable manner before the e-beam scan reaches the area of interest.

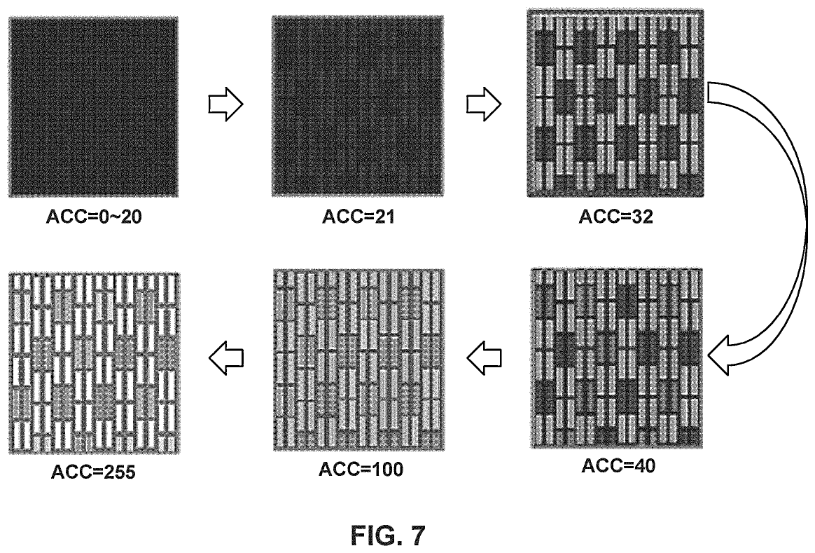

FIG. 7 illustrates the use of multiple imaging conditions that may be useful to find an optimal point for imaging, consistent with embodiments of the disclosure. During a scanning process, multiple SEM images may be taken at different imaging conditions to find the optimal VC signal in a defect inspection process. Imaging conditions may be adjusted by the charge regulator. For example, a series of SEM images with different ACC conditions are taken of the same area of interest for a semiconductor structure such as a Multi-Gate Chemical Mechanical Planarization (MGCMP) device layer. MEMS power modulation is used to image the device under a set of exemplary ACC levels, starting with a level between 0 and 20, and going up to ACC=255. Numerical values of ACC levels are arbitrary but may be representative of the power density of the laser spot illuminating the area of interest. When levels are too low, the image can be dark, the contrast can be poor, or features can be difficult to see. When levels are too high, features can be too bright and nonuniform. But at an intermediate value (e.g., around ACC=32 in the exemplary embodiment) the SEM gives high P/N contrast and good uniformity in both light and dark regions. In this way, MEMS power modulation can be used to tune a charge regulator (e.g., ACC power) or other parameters of a defect detection process.

Controller 109 of FIG. 2A (or ACC controller 140 of FIG. 2B) may include a feedback loop configured to optimize imaging conditions. Controller 109 may receive an inspection image, such as a SEM image. Controller 109 may analyze image parameters of the inspection image, such as contrast and brightness, or other image recognition or defect inspection parameters. The feedback loop may include adjusting a charge regulator parameter (such as an ACC power level) to optimize imaging conditions based on the image analysis.

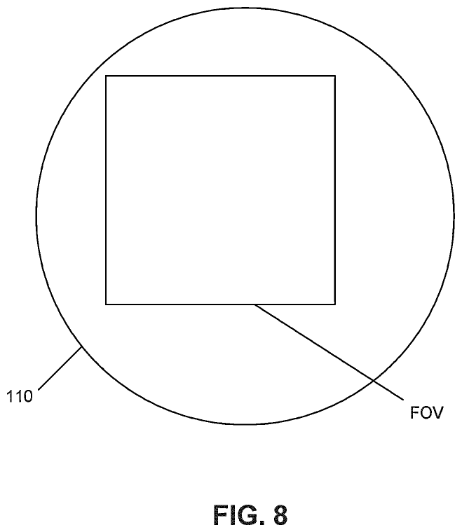

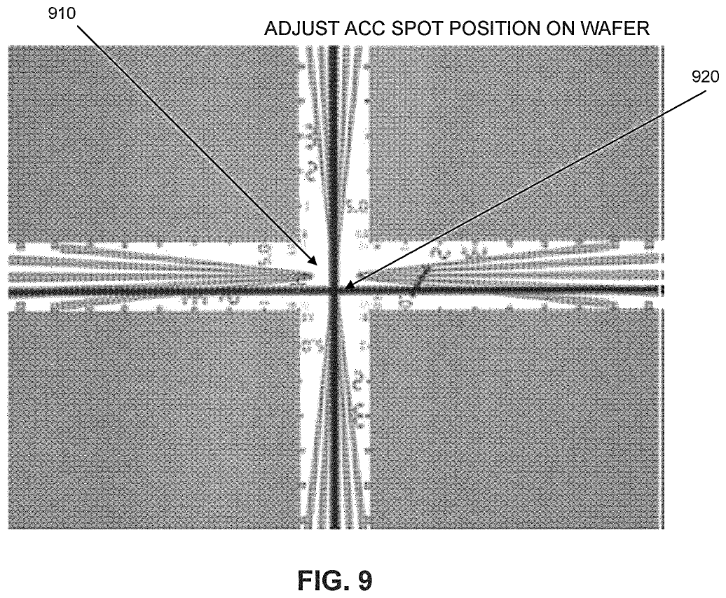

FIGS. 8 and 9 illustrate a top view of wafer 150 according to some embodiments of the present disclosure. In an embodiment, at least a component of the decentering of beam spot 110 from the FOV may be unintentional. As discussed above, an ACC laser module may periodically become misaligned. For example, one portion of the FOV may unintentionally become too close to the peripheral region of beam spot 110. This degrades illumination uniformity and defect detection performance. With an ACC module of a comparative embodiment, an operator would have to physically enter the SEM environment to manually adjust the beam based on alignment measurements from the SEM, for example, by turning knobs on the ACC module to adjust optical wedges. As shown in FIG. 9, an operator may view a monitor while adjusting optical wedges until a center region 910 of the ACC beam spot is roughly centered with respect to an alignment mark 920. This process is prone to error and inconsistency. In contrast, using an ACC module consistent with embodiments of the present disclosure, measurements can be used to remotely or automatically adjust the laser spot position using a beam manipulator, such as a MEMS mirror. Sensors may be provided to determine whether beam spot 110 is formed in a predetermined location. A feedback loop may be provided that measures parameters of beam spot 110 (e.g., location relative to an alignment mark) in real time, and adjustments may be made to charge regulator 108 based thereon. By feeding an alignment correction signal to ACC controller 140, an operator does not need to perform manual adjustments. In some embodiments, corrections are performed without stopping operation of the SEM. Therefore, downtime due to ACC alignment can be reduced or eliminated.

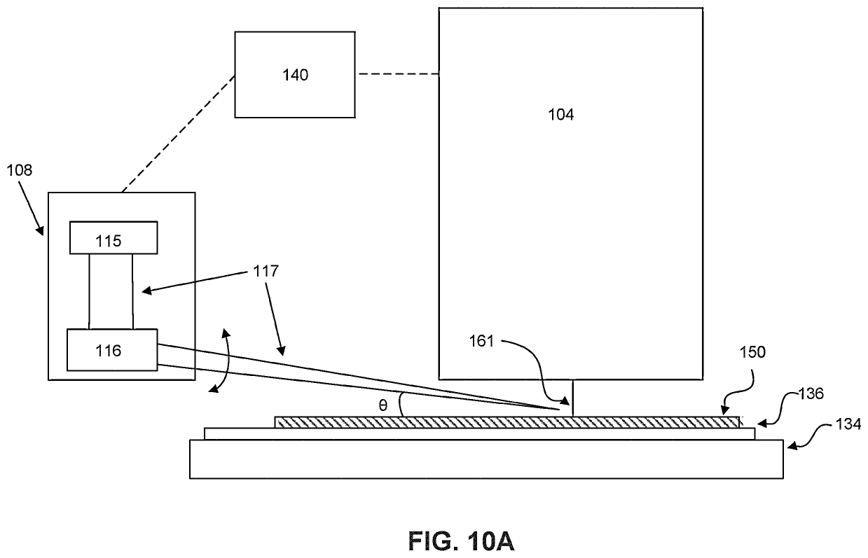

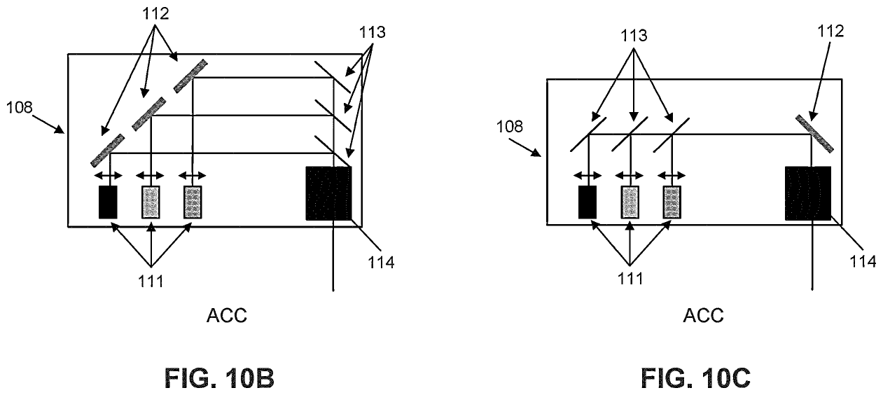

FIG. 10A is a diagrammatic representation of an internal configuration of a charge regulator along with a charged particle beam system, consistent with some embodiments of the present disclosure. Charge regulator 108 may include an ACC module. There may be provided a charge regulation source 115 and a beam manipulator 116. Charge regulation source 115 emits a beam 117 toward beam manipulator 116. Beam manipulator 116 manipulates beam 117 and directs it to wafer 150 consistent with some embodiments of the present disclosure. Charge regulator 108 may include further elements for conditioning, shaping, directing, deflecting, combining or otherwise modulating beam 117. Charge regulation source 115 may include a light source, such as a laser. Beam manipulator 116 may include a MEMS mirror.

FIGS. 10B and 10C schematically illustrate internal configurations of a charge regulator 108 consistent with some embodiments of the present disclosure. Charge regulator 108 may include an ACC module. There may be provided a plurality of light sources 111, a plurality of MEMS mirrors 112, a plurality of optical elements 113, and a lens 114. Light sources 111 may each be configured to generate a laser beam. Optical elements 113 may include dichroic mirrors. Beams generated from light sources 111 are overlapped to produce a beam spot at a common position on the sample surface. For example, light sources 111 may be combined to form beam spot 110 at a region of interest on a wafer. The light sources 111 may be of the same or different types. In some embodiments, each source among light sources 111 has a different center wavelength to allow combination by a series of dichroic mirrors included in optical elements 113. By combining multiple laser beams onto a common spot on the wafer, further increases in power density may be achieved.

MEMS mirrors 112 may be configured to manipulate beams that are input thereto. For example, MEMS mirrors 112 may adjust the size, shape, position, emission angle, power density, intensity distribution, or any other parameter of the beam so as to adjust properties of a beam spot formed on a surface of a sample onto which the beam is projected. Properties of the beam spot may be relative to a charged particle beam (e.g., an e-beam) that is also projected onto the sample surface. For example, the beam spot may be positioned in relation to the e-beam that scans over the sample. The beam spot may be formed so as to cover scan lines of the e-beam along one or more scanning directions. The beam spot may be formed so as to substantially cover a scan line along a first direction (e.g., a fast scan direction). For example, the beam spot may be at least a long as the e-beam scan line in the first direction. The beam spot may be formed so as to cover one or more scan lines along a second direction (e.g., a slow scan direction). For example, the beam spot may be at least as wide as one or more scan lines in the second direction.

MEMS mirrors 112 may be actuated so as to adjust their position (e.g., angle of incidence) relative to an input beam so as to affect the properties of the beam spot formed on the sample surface. MEMS mirrors 112 may condense a beam so as to form a condensed beam spot on a sample surface. MEMS mirrors 112 may expand a beam so as to form an expanded beam spot on the sample surface. The smaller the beam spot, the greater the power density of the formed beam spot. MEMS mirrors 112 may adjust a position of the beam spot formed on the sample surface. MEMS mirrors 112 may move a beam spot in relation to a scan path of the e-beam that is also projected onto the sample surface. The beam spot may be moved ahead of, behind, or in synch with the e-beam. For example, the beam spot may be controlled so as to follow the e-beam in at least one of the first direction (e.g., FS direction) and the second direction (e.g., SS direction). In some embodiments, MEMS mirrors 112 may have a transmissibility that affects the power density of the beam spot ultimately formed. For example, MEMS mirror 112 may be partially transmissible so that part of the input beam is directed toward the sample surface while part of the input beam is directed toward a sensor that is used for providing feedback. MEMS mirror 112 may be connected to a controller (e.g., controller 140 shown in FIG. 2A) and may be controlled to manipulate beams in real time during e-beam scanning.

FIG. 10B shows a configuration with multiple MEMS mirrors 112. As shown in FIG. 10B, MEMS mirrors 112 include one MEMS mirror for each of light sources 111, but other arrangements are contemplated within the scope of the invention. For example, a MEMS mirror that is large enough to accommodate multiple laser beams can be irradiated at distinct portions of the MEMS mirror surface and can be controlled to modulate each laser independently. MEMS mirrors 112 may be configured to direct light from light sources 111 onto a series of optical elements 113. Optical elements 113 combine the light from light sources 111 and deflect the combined beam through lens 114. Lens 114 may include a system of lenses to condition and focus an output beam. Lens 114 projects the combined beam to form a common laser spot on a portion of the wafer. For example, lens 114 may output beam spot 110 into wafer 150.

FIG. 10C shows a configuration in which a single MEMS mirror 112 is located downstream of optical elements 113. Here, the independent beams from light sources 111 are combined before they are incident on MEMS mirror 112. MEMS mirror 112 directs a combined beam through lens 114 and onto a common location on the wafer.

Other arrangements for combining multiple beams are possible. For example, light sources 111 need not have different wavelengths, and other beam combining elements may be used instead of dichroic mirrors. Furthermore, other optical elements may be provided, such as deflectors, mirrors, or lenses, for accomplishing other functions, such as beam steering.

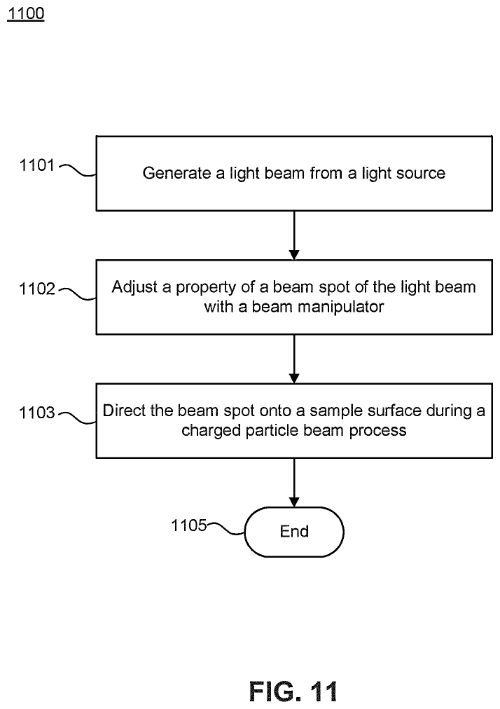

FIG. 11 illustrates a method 1100 for regulating sample surface charges in a charged particle beam system, consistent with some embodiments of the present disclosure. Method 1100 may be performed by ACC controller 140 of FIG. 2B or controller 109 of EBI system 100, as shown in FIG. 1, for example. Controller 109 may be programmed to implement one or more steps of method 1100. For example, controller 109 may instruct a module of a charged particle beam apparatus to regulate the sample surface charges.

At step 1101, a light source generates abeam. The beam may be a light beam, a laser beam, or other form of emitted energy. In some embodiments, the light source is a laser and the beam is a laser beam. In some embodiments, the light source may comprise a plurality of light sources such as a plurality of lasers. The lasers may emit light having different center wavelengths or different wavelength ranges. The lasers may emit light having substantially the same center wavelengths or overlapping wavelength ranges.

At step 1102, a beam spot of the beam is incident on a beam manipulator. The beam manipulator may be an optical element for manipulating a property of the beam spot. The property may relate to a size, shape, position, emission angle, power density, intensity distribution, or any other parameter of the beam so as to adjust properties of a beam spot formed on a surface of a sample onto which the beam is projected. The beam manipulator may include deflectors, apertures, diffractive optical elements, Fresnel lenses, micro-lenses, MEMS mirrors, deformable membrane mirrors, grating light valves (GLV), digital micromirror devices (DMD), or any structures capable of manipulating properties of beams. For example, there may be provided MEMS mirrors used in the beam manipulator that comprise a piece or an array (e.g., a two-dimensional planar array) of mirror elements. Each mirror element may have an area, e.g., on the order of microns and may be independently controllable. When a beam of light illuminates the MEMS mirror surface, each individual mirror element can be actuated to deflect one portion of the beam cross-section in a desired way. Together the mirrors can rapidly steer the beam direction, modulate the beam shape and adjust other beam parameters.

The beam manipulator may manipulate beam parameters so as to regulate sample surface charges in a charged particle beam system, such as the electron beam inspection system of FIGS. 1-2C. For example, controller 109 may control a MEMS mirror array to condense, adjust illumination characteristics, move, or shape the beam spot on the sample surface. The MEMS mirror may manipulate the beam spot to scan along with the electron beam. The MEMS mirror may manipulate the beam spot to modulate ACC power in real time during an electron beam scan. The MEMS mirror may manipulate the beam spot to smooth out speckle by repeatedly changing the beam spot position relative to an electron beam during a scan. The MEMS mirror may manipulate the beam spot to scan along the electron beam path with a time offset. The MEMS mirror may manipulate the beam spot to correct a misalignment.

At step 1103, the manipulator directs the manipulated beam spot onto a sample surface during a charged particle beam process. Directing the manipulated beam spot may include directing multiple beams onto a common surface. For example, controller 109 may control a plurality of MEMS mirrors to combine a plurality of light beams onto overlapping positions on a sample surface. Controller 109 may control a MEMS mirror to receive a plurality of beams from a beam combining element and direct the beams onto overlapping positions on the sample surface.

There may optionally be further elements along an optical path between the light source, beam manipulator and sample surface. For example, there may be a beam combining element. The beam combining element may include a dichroic mirror or other optical element for combine multiple light beams. Further, there may be a lens system to condition or focus the light beam. The lens system may include one or more lenses, apertures, mirrors, filters or other optical elements. The lens system may receive a light beam from a beam manipulator or beam combiner and focus or direct it onto the sample surface.

A non-transitory computer readable medium may be provided that stores instructions for a processor of a controller (e.g., controller 109 of FIG. 1 or controller 140 of FIG. 2B) for controlling the charge regulator, consistent with embodiments in the present disclosure. The controller may be configured cause the charge regulator to perform the various functions, actions, steps and sequences disclosed in the embodiments above. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

The embodiments may further be described using the following clauses:

1. A charge regulator for a charged particle beam tool, comprising:
a light source configured to emit a beam;
a beam manipulator configured to manipulate the beam; and
a controller configured to control the beam manipulator to adjust a property of a beam spot formed by the beam on a sample surface in relation to a charged particle beam projected on the sample surface.
   2. The charge regulator of clause 1, wherein the beam manipulator includes a MEMS mirror.
   3. The charge regulator of clause 1, wherein the light source is configured to emit a laser beam.
   4. The charge regulator of clause 1, wherein the charged particle beam is an electron beam in a scanning electron microscope.
   5. The charge regulator of clause 1, wherein the property is a position of the beam spot on the sample surface.
   6. The charge regulator of clause 1, wherein the property is a shape of the beam spot on the sample surface.
   7. The charge regulator of clause 1, wherein the property is a size of the beam spot on the sample surface.
   8. The charge regulator of clause 1, wherein the controller is configured to control the beam manipulator to scan the beam spot along the sample surface.
   9. The charge regulator of clause 8, wherein the property is a beam spot scanning direction along the sample surface.
   10. The charge regulator of clause 9, wherein the beam spot scanning direction includes a fast scan direction and a slow scan direction.
   11. The charge regulator of clause 8, wherein the beam spot scanning direction is parallel to a charged particle beam scanning direction of the charged particle beam projected on the sample surface.
   12. The charge regulator of clause 11, wherein the controller is configured to control the beam spot to follow the charged particle beam along the charged particle beam scanning direction.
   13. The charge regulator of clause 11, wherein the beam spot is scanned ahead of the charged particle beam with a time offset.
   14. A charged particle beam system, the system comprising:
a charged particle beam tool configured to emit a charged particle beam to expose a portion of a sample surface in a field of view of the charged particle beam tool; and
the charge regulator of clause 1.
   15. The charged particle beam system of clause 14, wherein the charged particle beam system is a multi-charged particle beam system.
   16. The charge regulator of clause 1, wherein:
the beam spot comprises an intensity distribution having a first region and a second region, the first region having a higher intensity than the second region; and
the controller is configured to control the beam manipulator to position the second region over an area of interest in a field of view of a charged particle beam tool during the projection of the charged particle beam on the sample surface.
   17. The charge regulator of clause 1, wherein the controller is configured to control the beam manipulator to adjust a position of the beam spot a plurality of times during the projection of the charged particle beam on the sample surface to average out speckle effects of the laser spot.
   18. The charge regulator of clause 1, wherein the controller is configured to control the beam manipulator to condense the beam spot on the sample surface.
   19. The charge regulator of clause 18, wherein the condensed spot has an area of less than 50% of an area of a field of view of a charged particle beam tool that projects the charged particle beam on the sample surface.
   20. The charge regulator of clause 1, wherein the controller is configured to control the beam manipulator to correct a misalignment between the beam spot and a field of view of a charged particle beam tool that projects the charged particle beam on the sample surface.
   21. The charge regulator of clause 20, wherein the correcting the misalignment is based on measurements from an alignment detector of a charged particle beam tool.
   22. The charge regulator of clause 1, wherein the charged particle beam tool is an electron beam inspection system for inspecting defects on a sample surface.
   23. The charge regulator of clause 1, further comprising:
a plurality of light sources configured to emit a plurality of beams;
an optical element configured to receive the plurality of beams.
   24. The charge regulator of clause 23, wherein
the beam manipulator is configured to receive the plurality of beams from the optical element and
overlap the plurality of beams onto a common portion of the sample surface.
   25. The charge regulator of clause 23, further comprising:
a plurality of beam manipulators;
wherein the plurality of beam manipulators is configured to direct the plurality of beams to the optical element and overlap the plurality of beams onto a common portion of the sample surface.
   26. The charge regulator of clause 23, wherein the optical element comprises a dichroic mirror.
   27. A method regulating surface charges on a sample surface in a charged particle beam tool, comprising:
emitting a beam from a light source;
manipulating the beam with a beam manipulator to adjust a property of a beam spot formed by the beam on a sample surface in relation to a charged particle beam projected on the sample surface.
   28. The method of clause 27, wherein the beam manipulator includes a MEMS mirror.
   29. The method of clause 27, wherein emitting the beam from the light source comprises emitting a laser beam.
   30. The method of clause 27, wherein the charged particle beam is an electron beam in a scanning electron microscope.
   31. The method of clause 27, wherein the property is a position of the beam spot on the sample surface.
   32. The method of clause 27, wherein the property is a shape of the beam spot on the sample surface.
   33. The method of clause 27, wherein the property is a size of the beam spot on the sample surface.
   34. The method of clause 27, wherein manipulating the beam manipulator includes controlling the beam manipulator to scan the beam spot along the sample surface.
   35. The method of clause 34, wherein the property is a beam spot scanning direction along the sample surface.
   36. The method of clause 35, wherein the beam spot scanning direction includes a fast scan direction and a slow scan direction.
   37. The method of clause 34, wherein the beam spot scanning direction is parallel to a charged particle beam scanning direction of the charged particle beam projected on the sample surface.
   38. The method of clause 37, wherein manipulating the beam manipulator includes controlling the beam spot to follow the charged particle beam along the charged particle beam scanning direction.
   39. The method of clause 37, further comprising scanning the beam spot ahead of the charged particle beam with a time offset.
   40. The method of clause 27, further comprising:
emitting the charged particle beam from a charged particle beam tool to expose a portion of the sample surface in a field of view of the charged particle beam tool.
   41. The method of clause 40, wherein mitting the charged particle beam comprises emitting multiple charged particle beams.
   42. The method of clause 27, wherein:
the beam spot comprises an intensity distribution having a first region and a second region, the first region having a higher intensity than the second region; and
wherein manipulating the beam manipulator includes controlling the beam manipulator to position the second region over an area of interest in a field of view of a charged particle beam tool during the projection of the charged particle beam on the sample surface.
   43. The method of clause 27, wherein manipulating the beam manipulator includes controlling the beam manipulator to adjust a position of the beam spot a plurality of times during the projection of the charged particle beam on the sample surface to average out speckle effects of the laser spot.
   44. The method of clause 27, wherein manipulating the beam manipulator includes controlling the beam manipulator to condense the beam spot on the sample surface.
   45. The method of clause 27, wherein the condensed spot has an area of less than 50% of an area of a field of view of a charged particle beam tool that projects the charged particle beam on the sample surface.
   46. The method of clause 27, wherein manipulating the beam manipulator includes controlling the beam manipulator to correct a misalignment between the beam spot and a field of view of a charged particle beam tool that projects the charged particle beam on the sample surface.
   47. The method of clause 46, wherein the correcting the misalignment is based on measurements from an alignment detector of a charged particle beam tool.
   48. The method of clause 27, wherein the charged particle beam is an electron beam in an electron beam inspection system for inspecting defects on a sample surface.
   49. The method of clause 27, further comprising:
emitting a plurality of beams a plurality of light sources;
receiving the plurality of beams at an optical element.
   50. The method of clause 49, further comprising:
receiving the plurality of beams from the optical element at the beam manipulator, and
overlapping the plurality of beams onto a common portion of the sample surface with the beam manipulator.
   51. The method of clause 49, further comprising:
manipulating the plurality of beams with a plurality of beam manipulators to direct the plurality of beams to the optical element and overlap the plurality of beams onto a common portion of the sample surface.
   52. The method of clause 49, wherein the optical element comprises a dichroic mirror.
   53. A non-transitory computer readable medium storing a set of instructions that is executable by one or more processors of a charged-particle beam apparatus to cause the charged particle beam apparatus to perform a method comprising:
emitting a beam from a light source;
manipulating the beam with a beam manipulator to adjust a property of a beam spot formed by the beam on a sample surface in relation to a charged particle beam projected on the sample surface.
   54. The non-transitory computer readable medium of clause 53, wherein the set of instructions is executable by one or more processors of a multi charged-particle beam apparatus.
   55. The non-transitory computer readable medium of clause 53, wherein the beam manipulator includes a MEMS mirror.
   56. The non-transitory computer readable medium of clause 53, wherein emitting the beam from the light source comprises emitting a laser beam.
   57. The non-transitory computer readable medium of clause 53, wherein the charged particle beam is an electron beam in a scanning electron microscope.
   58. The non-transitory computer readable medium of clause 53, wherein the property is a position of the beam spot on the sample surface.
   59. The non-transitory computer readable medium of clause 53, wherein the property is a shape of the beam spot on the sample surface.
   60. The non-transitory computer readable medium of clause 53, wherein the property is a size of the beam spot on the sample surface.
   61. The non-transitory computer readable medium of clause 53, wherein manipulating the beam manipulator includes controlling the beam manipulator to scan the beam spot along the sample surface.
   62. The non-transitory computer readable medium of clause 61, wherein the property is a beam spot scanning direction along the sample surface.
   63. The non-transitory computer readable medium of clause 62, wherein the beam spot scanning direction includes a fast scan direction and a slow scan direction.
   64. The non-transitory computer readable medium of clause 61, wherein the beam spot scanning direction is parallel to a charged particle beam scanning direction of the charged particle beam projected on the sample surface.
   65. The non-transitory computer readable medium of clause 64, wherein manipulating the beam manipulator includes controlling the beam spot to follow the charged particle beam along the charged particle beam scanning direction.
   66. The non-transitory computer readable medium of clause 64, wherein the set of instructions is executable by one or more processors of a charged-particle beam apparatus to cause the charged particle beam apparatus to further perform:
scanning the beam spot ahead of the charged particle beam with a time offset.
   67. The non-transitory computer readable medium of clause 53, wherein the set of instructions is executable by one or more processors of a charged-particle beam apparatus to cause the charged particle beam apparatus to further perform:
emitting the charged particle beam from a charged particle beam tool to expose a portion of the sample surface in a field of view of the charged particle beam tool.
   68. The non-transitory computer readable medium of clause 53, wherein:
the beam spot comprises an intensity distribution having a first region and a second region, the first region having a higher intensity than the second region; and
wherein manipulating the beam manipulator includes controlling the beam manipulator to position the second region over an area of interest in a field of view of a charged particle beam tool during the projection of the charged particle beam on the sample surface.
   69. The non-transitory computer readable medium of clause 53, wherein manipulating the beam manipulator includes controlling the beam manipulator to adjust a position of the beam spot a plurality of times during the projection of the charged particle beam on the sample surface to average out speckle effects of the laser spot.
   70. The non-transitory computer readable medium of clause 53, wherein manipulating the beam manipulator includes controlling the beam manipulator to condense the beam spot on the sample surface.
   71. The non-transitory computer readable medium of clause 53, wherein the condensed spot has an area of less than 50% of an area of a field of view of a charged particle beam tool that projects the charged particle beam on the sample surface.
   72. The non-transitory computer readable medium of clause 53, wherein manipulating the beam manipulator includes controlling the beam manipulator to correct a misalignment between the beam spot and a field of view of a charged particle beam tool that projects the charged particle beam on the sample surface.
   73. The non-transitory computer readable medium of clause 72, wherein the correcting the misalignment is based on measurements from an alignment detector of a charged particle beam tool.
   74. The non-transitory computer readable medium of clause 53, wherein the charged particle beam is an electron beam in an electron beam inspection system for inspecting defects on a sample surface.
   75. The non-transitory computer readable medium of clause 53, wherein the set of instructions is executable by one or more processors of a charged-particle beam apparatus to cause the charged particle beam apparatus to further perform:
emitting a plurality of beams a plurality of light sources; and
receiving the plurality of beams at an optical element.
   76. The non-transitory computer readable medium of clause 75, wherein the set of instructions is executable by one or more processors of a charged-particle beam apparatus to cause the charged particle beam apparatus to further perform:
receiving the plurality of beams from the optical element at the beam manipulator, and
overlapping the plurality of beams onto a common portion of the sample surface with the beam manipulator.
   77. The non-transitory computer readable medium of clause 75, wherein the set of instructions is executable by one or more processors of a charged-particle beam apparatus to cause the charged particle beam apparatus to further perform:
manipulating the plurality of beams with a plurality of beam manipulators to direct the plurality of beams to the optical element and overlap the plurality of beams onto a common portion of the sample surface.
   78. The non-transitory computer readable medium of clause 75, wherein the optical element comprises a dichroic mirror.
   79. A charge regulator for a charged particle beam tool, comprising:
a light source configured to emit a beam;
a beam manipulator configured to manipulate the beam; and
a controller configured to control the beam manipulator to regulate surface charges at a sample surface using the manipulated beam.
   80. A method for regulating surface charges on a sample surface in a charged particle beam tool, comprising:
emitting a beam from a light source;
manipulating the beam with a beam manipulator to regulate surface charges at a sample surface using the manipulated beam.
   81. A non-transitory computer readable medium storing a set of instructions that is executable by one or more processors of a charged-particle beam apparatus to cause the charged particle beam apparatus to perform a method comprising:
emitting a beam from a light source;
manipulating the beam with a beam manipulator to regulate surface charges at a sample surface using the manipulated beam.
   82. A charge regulator for a charged particle beam tool, comprising:
a light source configured to emit a beam;
a beam manipulator configured to manipulate the beam; and
a controller configured to regulate surface charges at a sample surface by controlling the beam manipulator to adjust a property of a beam spot formed by the beam on the sample surface in relation to a charged particle beam projected on the sample surface.
   83. A method for regulating surface charges on a sample surface in a charged particle beam tool, comprising:
emitting a beam from a light source;
regulating surface charges at a sample surface by manipulating the beam with a beam manipulator to adjust a property of a beam spot formed by the beam on a sample surface in relation to a charged particle beam projected on the sample surface.
   84. A non-transitory computer readable medium storing a set of instructions that is executable by one or more processors of a charged-particle beam apparatus to cause the charged particle beam apparatus to perform a method comprising:
emitting a beam from a light source;
regulating surface charges at a sample surface by manipulating the beam with a beam manipulator to adjust a property of a beam spot formed by the beam on a sample surface in relation to a charged particle beam projected on the sample surface
   85. A charge regulator for a charged particle beam tool, comprising:
a light source configured to emit a beam;
a power modulator configured to manipulate the beam to modulate beam power at a portion of a sample surface in relation to a charged particle beam projected on the sample surface.
   86. A method for regulating surface charges on a sample surface in a charged particle beam tool, comprising:
emitting a beam from a light source;
modulating power at a sample surface by manipulating the beam with a power modulator to modulate beam power at a portion of a sample surface in relation to a charged particle beam projected on the sample surface.
   87. A non-transitory computer readable medium storing a set of instructions that is executable by one or more processors of a charged-particle beam apparatus to cause the charged particle beam apparatus to perform a method comprising:
emitting a beam from a light source;
modulating power at a sample surface by manipulating the beam with a power modulator to modulate beam power at a portion of a sample surface in relation to a charged particle beam projected on the sample surface.
   88. A charged particle beam system, the system comprising:
a charged particle beam tool configured to emit a charged particle beam to expose a portion of a sample surface in a field of view of the charged particle beam tool;
an image detector configured to capture a charged particle beam image in the portion of the sample surface;
a charge regulator comprising:
a light source configured to emit a beam;
a beam manipulator configured to manipulate the beam; and
a controller configured to control the beam manipulator to adjust a property of a beam spot formed by the beam on a sample surface; and
a controller including circuitry configured to:
perform an image analysis of the charged particle beam image captured by the image detector; and
adjust a charge regulator parameter of the charge regulator based on the image analysis.
   89. A charged particle beam method, the method comprising:
emitting a charged particle beam from a charged particle beam tool to expose a portion of a sample surface in a field of view of the charged particle beam tool;
capturing a charged particle beam image in the portion of the sample surface with an image detector;
regulating charge at a sample surface by:
emitting a beam from a light source;
manipulating the beam with a beam manipulator; and
controlling the beam manipulator to adjust a property of a beam spot formed by the beam on a sample surface; and
performing an image analysis of the charged particle beam image captured by the image detector; and
adjusting a charge regulator parameter of the charge regulator based on the image analysis.
   90. A non-transitory computer readable medium storing a set of instructions that is executable by one or more processors of a charged-particle beam apparatus to cause the charged particle beam apparatus to perform a method comprising:
emitting a charged particle beam from a charged particle beam tool to expose a portion of a sample surface in a field of view of the charged particle beam tool;
capturing a charged particle beam image in the portion of the sample surface with an image detector;
regulating charge at a sample surface by:
emitting a beam from a light source;
manipulating the beam with a beam manipulator; and
controlling the beam manipulator to adjust a property of a beam spot formed by the beam on a sample surface; and
performing an image analysis of the charged particle beam image captured by the image detector; and
adjusting a charge regulator parameter of the charge regulator based on the image analysis.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein.

1. A charge regulator for a charged particle beam tool, comprising:
a light source configured to emit a beam;
a beam manipulator configured to manipulate the beam; and
a controller configured to control the beam manipulator to adjust a property of a beam spot formed by the beam on a sample surface in relation to a charged particle beam projected on the sample surface.

2. The charge regulator of claim 1, wherein the beam manipulator includes a MEMS mirror.

3. The charge regulator of claim 1, wherein the property is a position of the beam spot on the sample surface.

4. The charge regulator of claim 1, wherein the property is a shape of the beam spot on the sample surface.

5. The charge regulator of claim 1, wherein the controller is configured to control the beam manipulator to scan the beam spot along the sample surface.

6. The charge regulator of claim 5, wherein the beam spot scanning direction is parallel to a charged particle beam scanning direction of the charged particle beam projected on the sample surface.

7. The charge regulator of claim 5, wherein the beam spot is scanned ahead of the charged particle beam with a time offset.

8. The charge regulator of claim 1, wherein:
the beam spot comprises an intensity distribution having a first region and a second region, the first region having a higher intensity than the second region; and
the controller is configured to control the beam manipulator to position the second region over an area of interest in a field of view of a charged particle beam tool during the projection of the charged particle beam on the sample surface.

9. The charge regulator of claim 1, wherein the controller is configured to control the beam manipulator to adjust a position of the beam spot a plurality of times during the projection of the charged particle beam on the sample surface to average out speckle effects of the laser beam spot.

10. The charge regulator of claim 1, wherein the controller is configured to control the beam manipulator to condense the beam spot on the sample surface.

11. The charge regulator of claim 10, wherein the condensed spot has an area of less than 50% of an area of a field of view of a charged particle beam tool that projects the charged particle beam on the sample surface.

12. The charge regulator of claim 1, wherein the controller is configured to control the beam manipulator to correct a misalignment between the beam spot and a field of view of a charged particle beam tool that projects the charged particle beam on the sample surface.

13. The charge regulator of claim 1, further comprising:
a plurality of light sources configured to emit a plurality of beams;
an optical element configured to receive the plurality of beams.

14. A charged particle beam system, the system comprising:
a charged particle beam tool configured to emit a charged particle beam to expose a portion of a sample surface in a field of view of the charged particle beam tool; and
the charge regulator of claim 1.

15. A non-transitory computer readable medium storing a set of instructions that is executable by one or more processors of a charged-particle beam apparatus to cause the charged particle beam apparatus to perform a method comprising:
emitting a beam from a light source;
manipulating the beam with a beam manipulator to adjust a property of a beam spot formed by the beam on a sample surface in relation to a charged particle beam projected on the sample surface.

16. The non-transitory computer readable medium of claim 15, wherein the beam manipulator includes a MEMS mirror.

17. The non-transitory computer readable medium of claim 15, wherein the property is a position of the beam spot on the sample surface.

18. The non-transitory computer readable medium of claim 15, wherein the property is a shape of the beam spot on the sample surface.

19. The non-transitory computer readable medium of claim 15, wherein the property is a size of the beam spot on the sample surface.

20. The non-transitory computer readable medium of claim 15, wherein the property is a beam spot scanning direction along the sample surface.
